(19) United States
(12) Patent Application Publication
(10) Pub. No.: US 2007/0122935 A1
(43) Pub. Date: May 31, 2007

(54) Manufacturing method of solid-state imaging device, solid-state imaging device, and camera

(76) Inventors: Masahiro Kasano, Osaka (JP); Yuichi Inaba, Osaka (JP); Keisuke Tanaka, Osaka (JP); Takumi Yamaguchi, Kyoto (JP)

Correspondence Address: MCDERMOTT WILL & EMERY LLP, 600 13TH STREET, N.W., WASHINGTON, DC, 20005-3096, US

(21) Appl. No.: 11/602,179

(22) Filed: Nov. 21, 2006

(30) Foreign Application Priority Data
Nov. 25, 2005 (JP) 2005-341102

(51) Int. Cl. H01L 21/00

(52) U.S. Cl. 438/73

(57) ABSTRACT

A manufacturing method of a solid-state imaging device prevents generation of a space due to insufficient filling of a conductive material. Materials constituting a multilayer film 41 are sequentially deposited on a semiconductor substrate, and portions respectively included in a plug formation intended region and a surrounding region that surrounds the plug formation intended region are removed from the deposited multilayer film 41. Next, the plug formation intended region and the surrounding region from which the portions have been removed is refilled with a single insulating material, and a hole is formed on the plug formation intended region by etching. Then, the formed hole is filled with a conductive material to therefore form a plug.

### BACKGROUND OF THE INVENTION

(1) Field of the Invention

The present invention relates to a manufacturing method of a solid-state imaging device for use in digital cameras etc.

(2) Related Art

In recent years, various color filters composed of inorganic materials have been proposed as color filters for use in solid-state imaging devices. For example, WO 2005/069376 discloses a color filter composed of a multilayer film obtained by laminating seven layers made from two kinds of inorganic materials. By adopting an inorganic material as a material constituting a color filter, the color filter can be formed using semiconductor process, and can be provided between a wiring layer and a substrate layer, or between wiring layers of multilayer wirings (See WO 2005/069376, FIG. 25). Provision of a color filter between wiring layers etc. is considered to highly enhance usefulness in terms of design flexibility and prevention of color-mixing.

If providing a color filter between wiring layers etc., the wiring layers need to be electrically connected with each other via a plug that penetrates the color filter. Generally, the plug is formed by forming a hole in the color filter using anisotropic etching, and then filling the hole with a conductive material using a CVD (Chemical Vapor Deposition) method.

However, if the color filter is composed of a multilayer film, the above-mentioned method might cause the following defect.

Anisotropic etching is far excellent in selecting an etching direction in comparison with isotropic etching. However, side etching inevitably occurs in the anisotropic etching to some extent. Since a material of a multilayer film is different for each layer, a side etching speed is different for each layer. Accordingly, an inner diameter of a hole obtained by etching might be different for each layer. As a result, a space is easily generated between an inner wall of the hole and a conductive material. Particularly, a layer in which a smaller hole inner diameter is positioned tends to become a protrusion in a layer in which a larger hole inner diameter is positioned. Therefore, this easily results in generation of a space. This space might cause deterioration of electrical characteristics of plugs. For example, liquid etc. remain in such space, and as a result a plug rusts.

### SUMMARY OF THE INVENTION

In view of the above problem, the present invention aims to provide a manufacturing method of a solid-state imaging device, the solid-state imaging device, and a camera that are capable of preventing generation of a space due to insufficient filling of a conductive material, even if adopting a structure where a color filter composed of a multilayer film is provided between wiring layers etc.

In order to solve the above problem, a manufacturing method of a solid-state imaging device according to the present-invention is a manufacturing method of a solid-state imaging device including a multilayer film and a plug that penetrates the multilayer film, and the manufacturing method comprises: a multilayer film forming step of forming a multilayer film; a removing step of removing, from the formed multilayer film, portions respectively included in a plug formation intended region in which a plug is to be formed and a surrounding region that surrounds the plug formation intended region; a refilling step of refilling, with a single insulating material, the plug formation intended region and the surrounding region from which the portions have been removed; a hole forming step of forming a hole in the refilled plug formation intended region by etching; and a plug forming step of forming the plug by filling the formed hole with a conductive material.

With the above structure, since etching is performed on a single insulating material in the hole forming step, a side etching speed is uniform. Accordingly, a hole obtained by etching has a shape having the substantially uniform inner diameter or a tapered shape in which an inner diameter continuously becomes smaller toward a bottom of the hole. If the hole has such shape, the conductive material can be filled in the hole without generating a space in the filling step. Therefore, even if adopting a structure where a color filter composed of a multilayer film is provided between wiring layers etc., the present invention can prevent generation of a space due to insufficient filling of the conductive material.

Also, the multilayer film may cover a semiconductor substrate including a pixel region in which pixels are arranged, and a peripheral region in which circuits are arranged and that is on a periphery of the pixel region, and the peripheral region may be covered by the portions of the multilayer film.

Generally, in a multilayer film, many plugs are formed in a region that covers a peripheral region. With the above structure, many portions included in the plug formation intended region are collectively removed. Therefore, alignment accuracy needed for alignment devices can be suppressed in comparison with the case where portions included in the plug formation intended region are removed one by one. As a result, manufacturing costs can be reduced.

Also, the removing step may be performed such that the surrounding region has a width of at least 0.1 μm in a direction extending the plug formation intended region.

Within the above numerical range, a plug can be formed using a general-purpose manufacturing device in terms of alignment accuracy. As a result, manufacturing costs can be reduced.

Also, the multilayer film may have a depression between pixels due to a difference in thickness of the multilayer film for each pixel, and the refilling step may further fill the depression with the single insulating material.

Also, the refilling step may comprise: a depositing substep of depositing the single insulating material on the multilayer film so as to at least flatten the depression and the plug formation intended region and the surrounding region from which the portions have been removed; and a polishing substep of polishing the deposited insulating material so as to expose a highest main face of the multilayer film.

With the above structure, flattening can be performed in the refilling step. Therefore, in the plug forming step, a conductive material is deposited in a flattened insulating material so as to fill a hole. And then, the conductive material deposited on the flattened insulating material can be removed. In this case, since the insulating material is flattened, an unnecessarily deposited conductive material can be easily removed.

A solid-state imaging device according to the present invention comprises: a multilayer film; and a plug that penetrates the multilayer film, wherein a region included in the multilayer film that surrounds the plug is composed of a single insulating material.

With the above structure, portions included in a plug formation intended region and a surrounding region that surrounds the plug formation intended region are removed from a multilayer film, the plug formation intended region and the surrounding region from which the portions have been removed are refilled with a single insulating material, a hole is formed in the plug formation intended region, and then a plug is formed.

A solid-state imaging device manufactured in this way can prevent generation of a space due to insufficient filling of a conductive material, even if adopting a structure where a color filter composed of a multilayer film is provided between wiring layers etc.

Also, the multilayer film covers a semiconductor substrate including a pixel region in which pixels are arranged, and a peripheral region in which circuits are arranged and that is on a periphery of the pixel region, and a region included in the multilayer film that covers the peripheral region and excludes the plug is the region that surrounds the plug.

With the above structure, many portions included in a plug formation intended region are collectively removed. Therefore, alignment accuracy needed for alignment devices can be suppressed in comparison with the case where portions included in the plug formation intended region are removed one by one. As a result, manufacturing costs can be reduced.

A camera according to the present invention includes the above-described solid-state imaging device.

With the above structure, the same effects as the above-described effects can be achieved.

### BRIEF DESCRIPTION OF THE DRAWINGS

These and other objects, advantages and features of the invention will become apparent from the following description thereof taken in conjunction with the accompanying drawings which illustrate a specific embodiment of the invention.

In the Drawings:

FIG. 1 is a full view showing a camera according to the present invention;

FIG. 2 is a top view showing a layout in a solid-state imaging device according to the present invention;

FIG. 3 is a partial sectional view showing a solid-state imaging device according to a first embodiment;

FIG. 4 shows light transmission characteristics of a color filter composed of a multilayer film according to the first embodiment;

FIG. 5 is a sectional view showing a process of a manufacturing method of the solid-state imaging device according to the first embodiment;

FIG. 6 is a sectional view showing a process of the manufacturing method of the solid-state imaging device according to the first embodiment;

FIG. 7 is a sectional view showing a process of the manufacturing method of the solid-state imaging device according to the first embodiment;

FIG. 8 is a partial enlarged view showing a plug that penetrates a multilayer film of the solid-state imaging device manufactured using the manufacturing method according to the first embodiment;

FIG. 9 is a partial sectional view showing a solid-state imaging device according to a second embodiment;

FIG. 10 is a partial sectional view showing a solid-state imaging device according to a first modification; and

FIG. 11 is a partial sectional view showing a solid-state imaging device according to a second modification.

### DESCRIPTION OF THE PREFERRED EMBODIMENTS

The following describes preferred embodiments to implement the present invention in detail with reference to the drawings.

(First Embodiment)

<Structure>

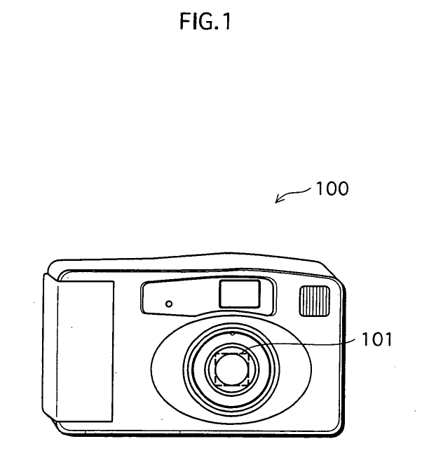

FIG. 1 is a full view showing a camera according to the present invention.

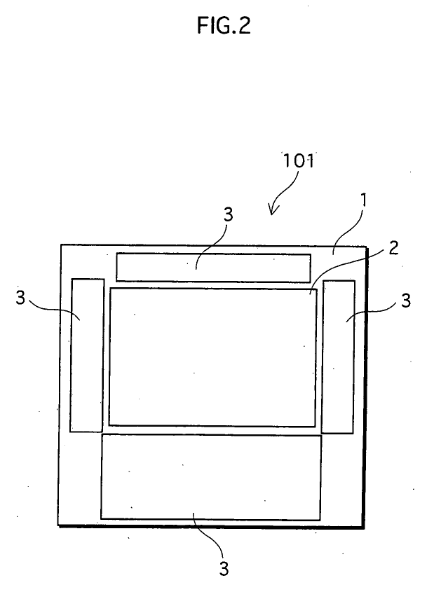

FIG. 2 is a top view showing a layout in a solid-state imaging device according to the present invention.

As shown in FIG. 1, a camera 100 includes a built-in solid-state imaging device 101. Also, as shown in FIG. 2, a semiconductor substrate 1 includes a pixel region 2 where pixels are arranged and peripheral regions 3 on a periphery of the pixel region 2 and in each which circuits are arranged. In each of the peripheral regions 3, a vertical scanning circuit, a horizontal scanning circuit, an amplifying circuit, etc. are arranged.

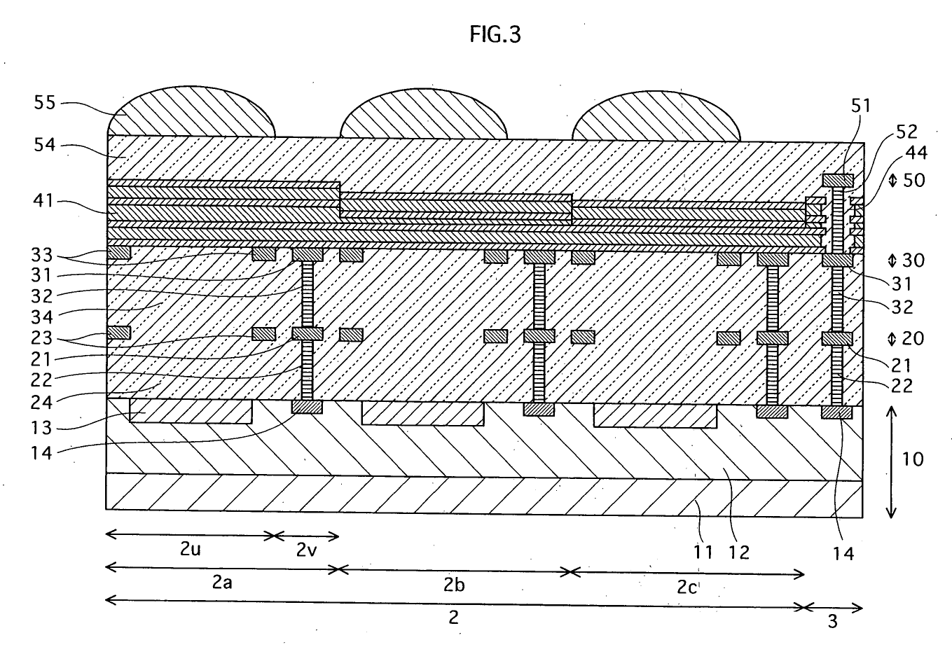

FIG. 3 is a partial sectional view showing a solid-state imaging device according to a first embodiment.

The solid-state imaging device 101 includes a substrate layer 10, wiring layers 20, 30, and 50. The layers are insulated from each other by interlayer insulation films 24, 34, 44, and 54 respectively, each which is composed of silicon dioxide etc. Moreover, a multilayer film 41 that functions as a color filter is disposed between the wiring layer 30 and the wiring layer 50.

The substrate layer 10 is composed of a semiconductor substrate 11 in which a well 12 is formed. An impurity diffusion region 13 that functions as a photodiode and an impurity diffusion region 14 as a part of a transistor are formed in the well 12 for each of pixels 2a, 2b, and 2c.

Wirings 21, 31, and 51 are formed using a conductive material such as tungsten in the wiring layers 20, 30, and 50 respectively. Furthermore, light shielding films 23 and 33 are formed using the conductive-material that constitutes the wirings 21, 31, and 51. The substrate layer 10, the wiring layers 20, 30, and 50 are electrically connected with each other via plugs 22, 32, and 52. Each of the plugs 22, 32, and 52 is also composed of a conductive material such as tungsten.

The multilayer film 41 has a seven-layer structure in which a monolayer film referred to as a spacer layer is sandwiched between two three-layer films. The monolayer film is composed of silicon dioxide, and a thickness thereof is adjusted in accordance a thickness of a film defined for each of the pixels 2a, 2b, and 2c. Each of the three-layer films has the following structure: titanium dioxide (52 nm)/nitrogen dioxide (91 nm)/titanium dioxide (52 nm).

In the present invention, a region that surrounds the plug 52 in the multilayer film 41 is an interlayer insulation film 44 that is composed of a single insulating material.

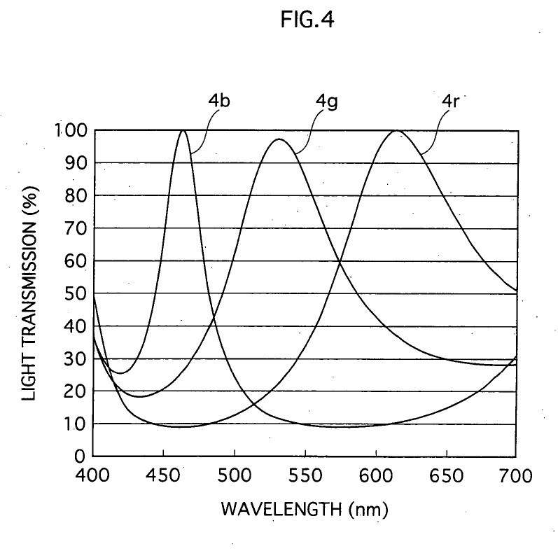

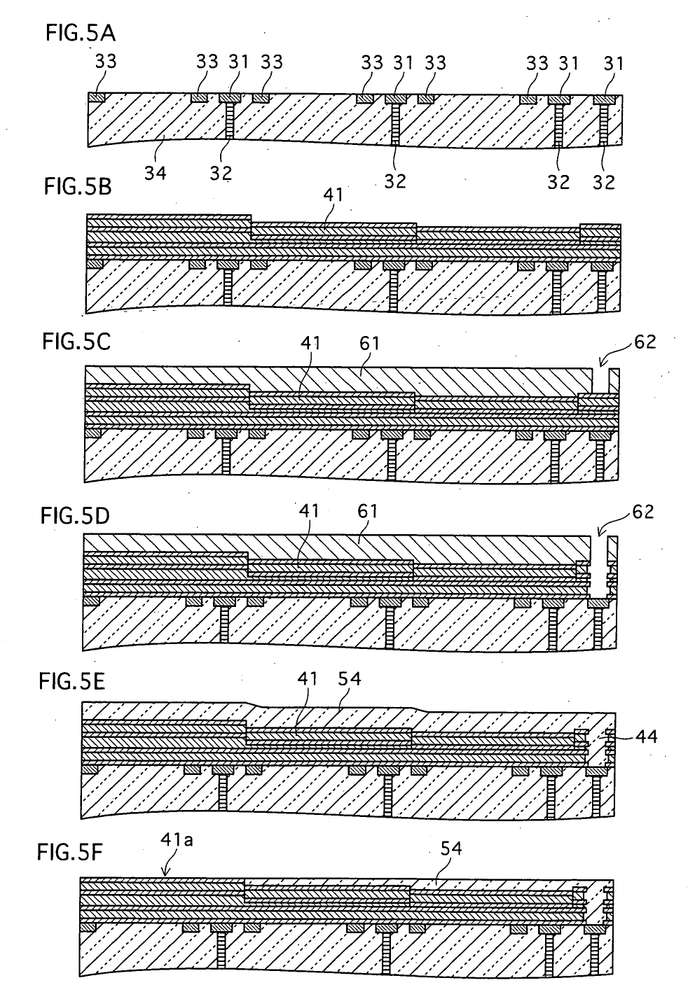

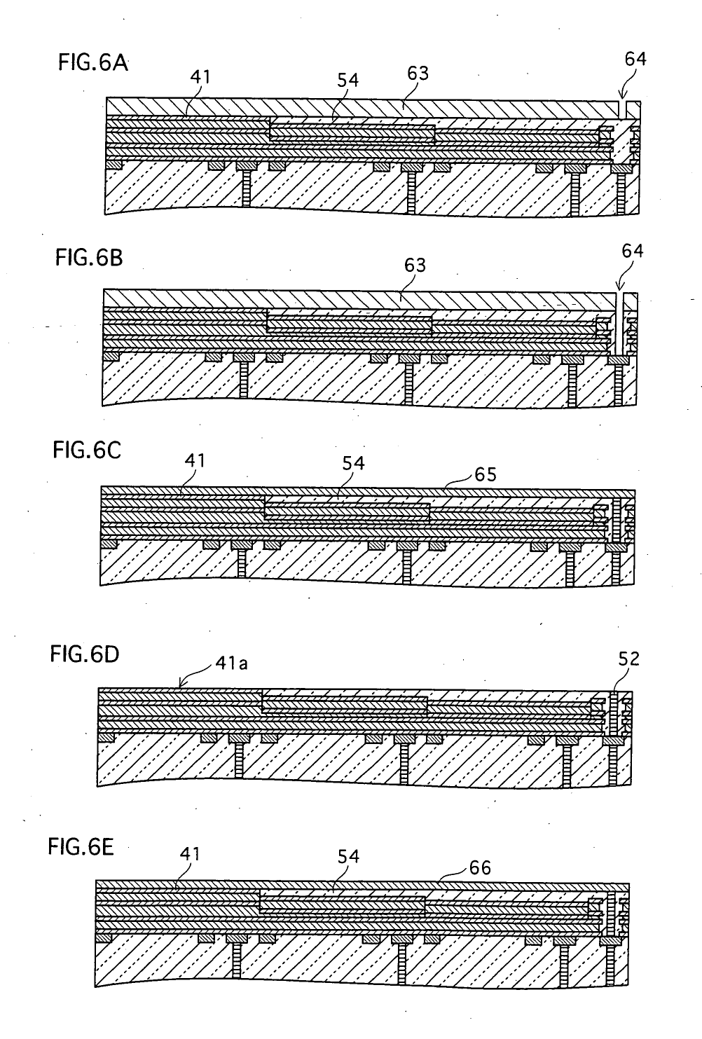

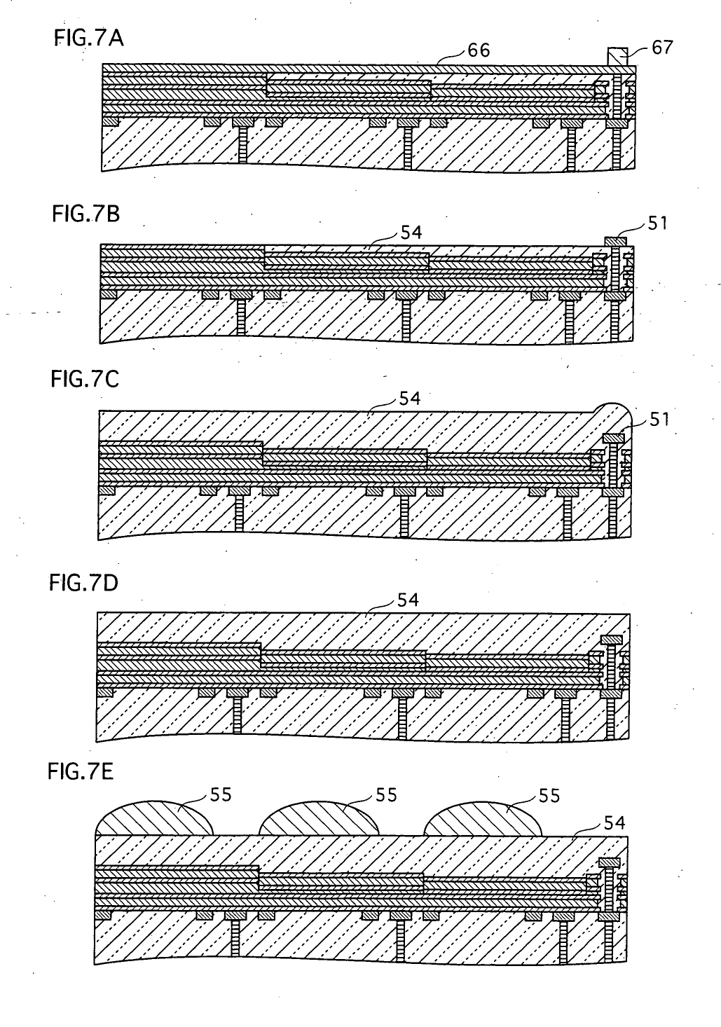

In addition, the multilayer film 41 can have different light transmission characteristics depending on a thickness of the monolayer film (FIG. 4). Here, the monolayer film has a thickness of 133 nm, 31 nm, and 0 nm in the pixels of blue, red, and green, respectively. In FIG. 4, curves 4b, 4g, and 4r show light transmission characteristics in the pixels of blue, green, and red, respectively.

<Manufacturing Method>FIG. 5, FIG. 6, and FIG. 7 are sectional views showing processes of a manufacturing method of the solid-state imaging device according to the first embodiment.

First, the substrate layer 10, the wiring layers 20 and 30 are formed (FIG. 5A). The substrate layer 10 and the wiring layer 20 are not shown in FIG. 5A.

In order to form the multilayer film 41 as a color filter, materials (titanium dioxide and nitrogen dioxide) constituting the multilayer film 41 are sequentially deposited on the wiring layer 30 (FIG. 5B). The multilayer film 41 is formed so as to have a different thickness for each pixel.

Subsequently, portions respectively included in a plug formation intended region in which a plug is to be formed and a surrounding region that surrounds the plug formation intended region are removed from the multilayer film 41. In order to remove the portions, an etching mask 61 is formed on the multilayer film 41 (FIG. 5C). The etching mask 61 has an aperture 62 in a portion corresponding to the plug formation intended region and the surrounding region. Here, the portions respectively included in the plug formation intended region and the surrounding region are removed such that the surrounding region has a width of at least 0.1 μm in a direction extending the plug formation intended region.

Then, anisotropic etching is performed (FIG. 5D). As a result, the portions respectively included in the plug formation intended region and the surrounding region can be removed from the multilayer film 41.

Next, the plug formation intended region and the surrounding region from which the portions have been removed using the etching is refilled with a single insulating material (for example, silicon dioxide that is the same material as that of the interlayer insulation film 44). The single insulating material is deposited so as to flatten a depression between pixels due to a difference in thickness of the multilayer film for each pixel (FIG. 5E). For example, silicon dioxide is deposited using a CVD method. Subsequently, the deposited insulating material is polished using a CMP method so as to expose a highest main face 41a of the multilayer film 41 (FIG. 5F). In this way, the plug formation intended region and the surrounding region from which the portions have been removed can be refilled, and a surface of the multilayer film 41 can be flattened.

Next, a hole is formed by etching in the refilled plug formation intended region. In order to form the hole, an etching mask 63 is formed on the multilayer film 41 (FIG. 6A). The etching mask 63 has an aperture 64 in a portion corresponding to the plug formation intended region. Then, anisotropic etching is performed (FIG. 6B) As a result, the hole can be formed in the plug formation intended region.

Next, a plug is formed by filling the hole with a conductive material (for example, tungsten). In order to form the plug, the conductive material is deposited so as to at least fill the hole with the conductive material (FIG. 6C). Tungsten is deposited using a tungsten CVD method, for example.

If using the tungsten CVD method, the conductive material is deposited not only in the hole but also on the interlayer insulation film 54. Accordingly, the conductive material unnecessarily deposited on the interlayer insulation film 54 needs to be removed. Therefore, whole the deposited conductive material is polished using the CMP method so as to expose the highest main face 41a of the multilayer film 41 (FIG. 6D). In this way, the hole can be filled with the conductive material. Also, since the surface of the multilayer film 41 has been already flattened in the refilling process (FIG. 5F), the unnecessarily deposited conductive material can be easily removed by polishing.

Next, a wiring is formed in the wiring layer 30. A conductive material (for example, tungsten) is deposited on the multilayer film 41 such that the wiring has an intended thickness (FIG. 6E). Then, an etching mask 67 corresponding to a wiring pattern is formed (FIG. 7A), and etching is performed (FIG. 7B) As a result, the wiring is formed in the wiring layer 30.

Lastly, the interlayer insulation film 54 is deposited on the wiring layer 30 (FIG. 7C), and the deposited interlayer insulation film 54 is flattened (FIG. 7D). And then, a micro lens 55 is formed (FIG. 7E).

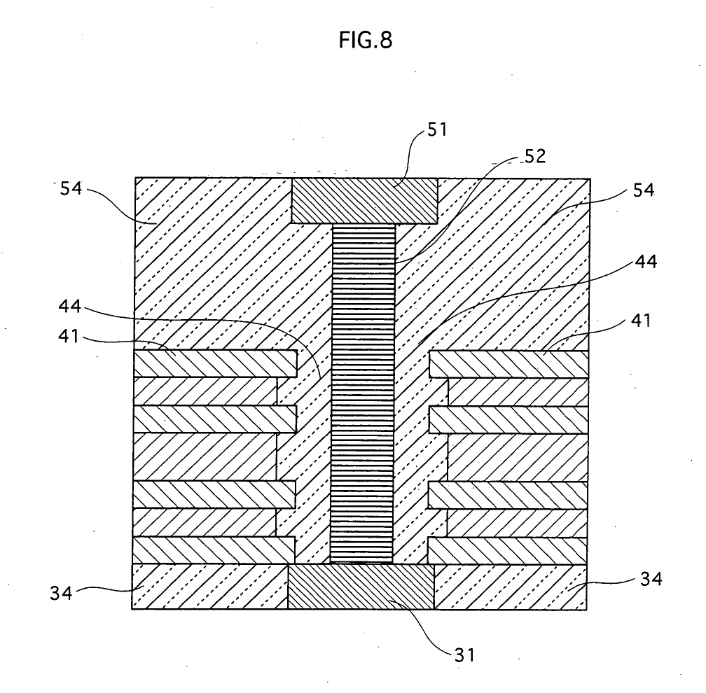

FIG. 8 is a partial enlarged view showing the solid-state imaging device manufactured using the manufacturing method according to the first embodiment.

A peripheral portion of the plug 52 is enlarged in FIG. 8. The plug 52 has the substantially uniform diameter. This is because since side etching is performed on the interlayer insulation film 44 composed of the single insulating material, a side etching speed is the substantially uniform and as a result a hole having the substantially uniform inner diameter is formed. Moreover, no space exists between the plug 52 and the interlayer insulation film 44. This is because the hole has the substantially uniform inner diameter and therefore no protrusion exists.

(Second Embodiment)

A second embodiment is characterized in that a region that covers a peripheral region 3 is removed in a process of partially removing a region in a multilayer film 41. The description except for this is omitted here since the second embodiment has the same structure as that of the first embodiment.

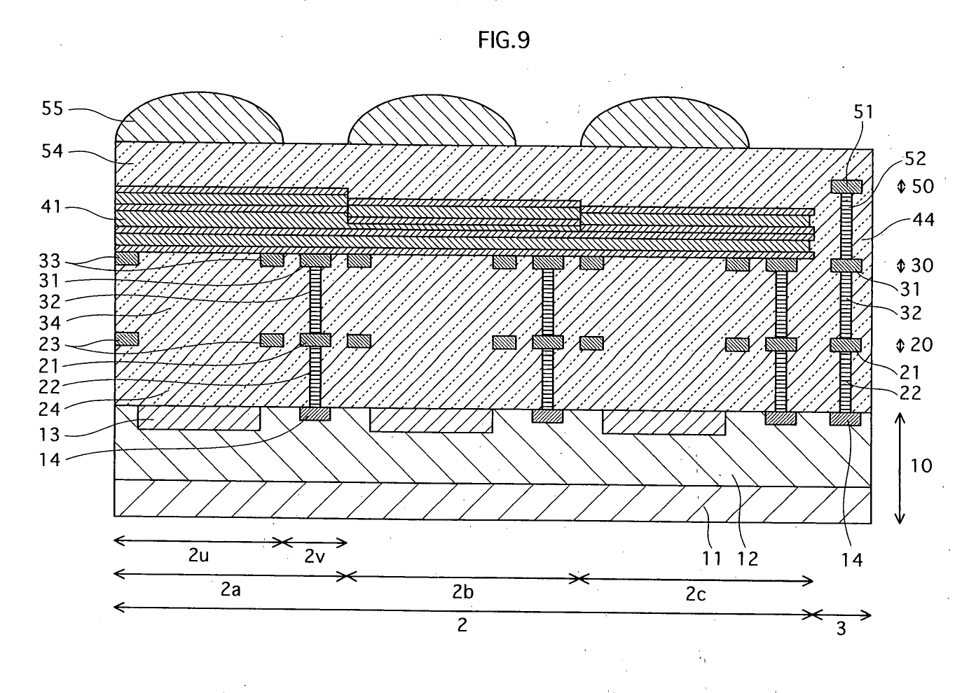

FIG. 9 is a partial sectional view showing a solid-state imaging device according to the second embodiment.

As shown in FIG. 9, in the multilayer film 41, the region that covers the peripheral region 3 is replaced with an interlayer insulation film 44 composed a single insulating material. A plug 52 is formed in the interlayer insulation film 44.

Generally, in the multilayer film 41, many plugs are included in the region that covers the peripheral region 3. In the second embodiment, the portions included in the region that covers the peripheral region 3 is removed. Therefore, alignment accuracy needed for alignment devices can be suppressed in comparison with the case of the first embodiment where the portions included in the plug formation intended region are removed one by one from the multilayer film 41. As a result, manufacturing costs can be reduced.

Although the manufacturing method of the solid-state imaging device according to the present invention has been described based on the above embodiments, the present invention-is not of course limited to these embodiments, and further includes the following modifications, for example.
(1) In the embodiments, the plug that penetrates the multilayer film 41 exists only in the peripheral region 3. However, a plug that penetrates the multilayer film 41 also exists in the pixel region 2,. as described below.

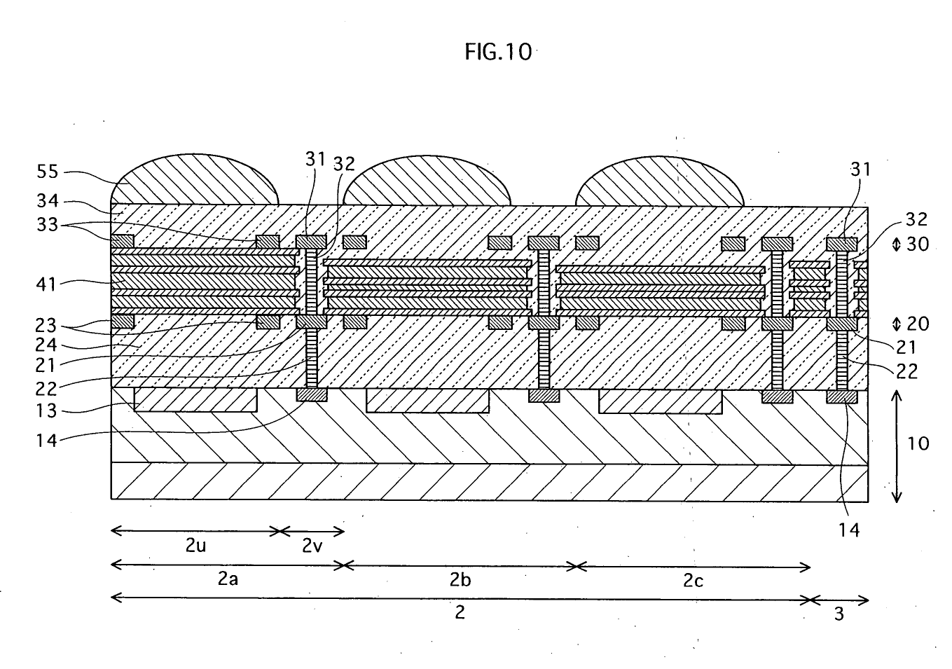

FIG. 10 is a partial sectional view showing a solid-state imaging device according to a first modification.

As shown in FIG. 10, a multilayer film 41 that functions as a color filter is disposed between a wiring layer 20 and a wiring layer 30. Each pixel has a light receiving region 2u and a pixel circuit region 2v. Generally, on the pixel circuit region 2v, a read transistor, a reset transistor, an amplification transistor, a line selection transistor, and a circuit are arranged. The circuit is composed of wirings that connect these transistors with each other. In the first modification, the circuit arranged on the pixel circuit region 2v uses the wiring layer 30. Accordingly, a plug 32 that penetrates the multilayer film 41 exists not only in a peripheral region 3 but also in a pixel region 2.

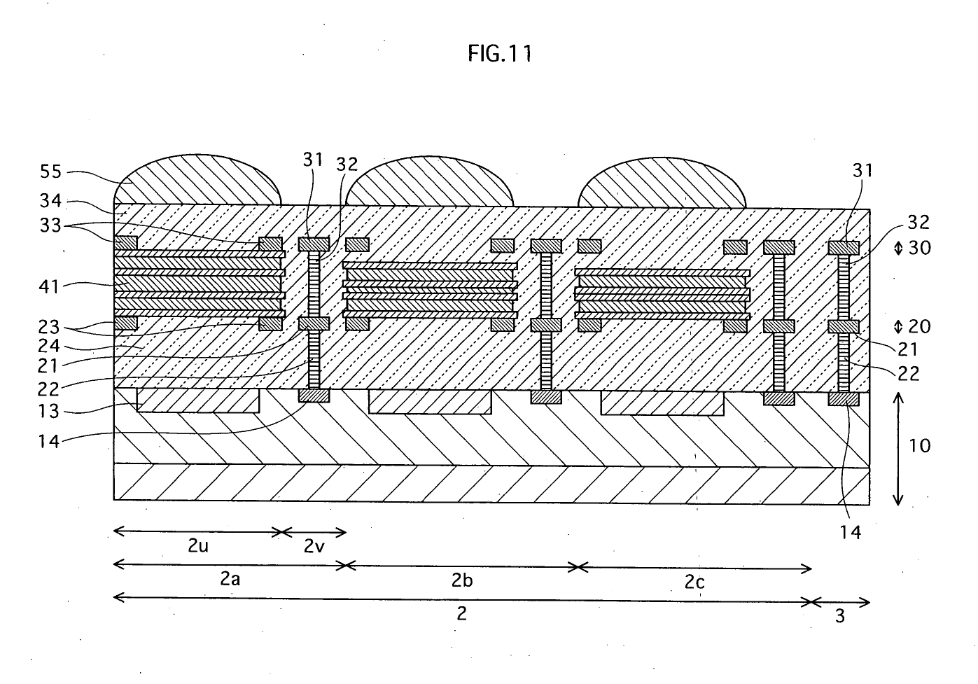

FIG. 11 is a partial sectional view showing a solid-state imaging device according to a second modification.

In the second modification, in a process of partially removing a region in a multilayer film 41, a region that covers a pixel circuit region 2v and a region that covers a peripheral region 3 are removed from multilayer film 41. This process differs from the process in the first modification. Generally, in the multilayer film 41, many plugs are included in the region that covers the pixel circuit region 2v. In the second modification, the region that covers the pixel circuit region 2v is removed. Therefore, alignment accuracy needed for alignment devices can be suppressed in comparison with the case of the first modification where the portions included in the plug formation intended region are removed one by one from the multilayer film 41. As a result, manufacturing costs can be reduced.
(2) In the first modification, in both the pixel region 2 and the peripheral region 3, the portions included in the plug formation intended region are removed one by one from the multilayer film 41. Also, in the second modification, in both the pixel region 2 and the peripheral region 3, the portions included in regions that include many plug formation intended regions are collectively removed from the multilayer film 41. However, the portions included in the plug formation intended region have no need to be removed in the same way in the pixel region 2 and the peripheral region 3. For example, portions included in a plug formation intended region may be removed one by one in the pixel region 2, and portions included in a plug formation intended region may be collectively removed in the peripheral region 3.
(3) In the embodiments and the modifications, the multilayer film 41 is provided between the wiring layers of the multilayer wirings. However, the present invention is not limited to the embodiments and the modifications. The present invention can be applied to an example where the multilayer film 41 is provided between the substrate layer 10 and the wiring layer 20.
(4) In the embodiments, the multilayer film 41 has a seven-layer structure. However, the multilayer film 41 may have any multilayer structure. Also, in the embodiments, the multilayer film 41 is a symmetric figure in a lamination direction. However, the multilayer film 41 may not be a symmetric figure. Furthermore, in the embodiments, the multilayer film 41 is composed of a combination of titanium dioxide and nitrogen dioxide. However, materials for the multilayer film 41 are not limited to being titanium dioxide and nitrogen dioxide mentioned in the above description. Any combination of tantalum oxide (Ta₂O₅), zirconium oxide (ZrO₂), silicon nitride (SiN), silicon nitride (Si₃N₄), aluminum oxide (Al₂0₃), magnesium fluoride (MgF₂), or hafnium oxide (HfO₃) magnesium oxide (MgO₂) may also be used.
(5) In the embodiments, the example where a plug is formed in a multilayer film used as a color filter has been described. However, the present invention is not limited to this example, and can be applied to the case where. a plug is formed in a multilayer film used as other functions such as a reflecting film.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be construed as being included therein.

What is claimed is:

1. A manufacturing method of a solid-state imaging device including a multilayer film and a plug that penetrates the multilayer film, the manufacturing method comprising:
a multilayer film forming step of forming a multilayer film;
a removing step of removing, from the formed multilayer film, portions respectively included in a plug formation intended region in which a plug is to be formed and a surrounding region that surrounds the plug formation intended region;
a refilling step of refilling, with a single insulating material, the plug formation intended region and the surrounding region from which the portions have been removed;
a hole forming step of forming a hole in the refilled plug formation intended region by etching; and
a plug forming step of forming the plug by filling the formed hole with a conductive material.

2. The manufacturing method of claim 1, wherein
the multilayer film covers a semiconductor substrate including a pixel region in which pixels are arranged, and a peripheral region in which circuits are arranged and that is on a periphery of the pixel region, and
the peripheral region is covered by the portions of the multilayer film.

3. The manufacturing method of claim 1, wherein
the removing step is performed such that the surrounding region has a width of at least 0.1 μm in a direction extending the plug formation intended region.

4. The manufacturing method of claim 1, wherein
the multilayer film has a depression between pixels due to a difference in thickness of the multilayer film for each pixel, and
the refilling step further fills the depression with the single insulating material.

5. The manufacturing method of claim 4, wherein
the refilling step comprises:
a depositing substep of depositing the single insulating material on the multilayer film so as to at least flatten the depression and the plug formation intended region and the surrounding region from which the portions have been removed; and
a polishing substep of polishing the deposited insulating material so as to expose a highest main face of the multilayer film.

6. A solid-state imaging device comprising:
a multilayer film; and
a plug that penetrates the multilayer film, wherein
a region included in the multilayer film that surrounds the plug is composed of a single insulating material.

7. The solid-state imaging device of claim 6, wherein
the multilayer film covers a semiconductor substrate including a pixel region in which pixels are arranged, and a peripheral region in which circuits are arranged and that is on a periphery of the pixel region, and
a region included in the multilayer film that covers the peripheral region and excludes the plug is the region that surrounds the plug.

8. A camera including the solid-state imaging device of claim 6.
